(19) United States
(12) Patent Application Publication
(10) Pub. No.: US 2026/0302714 A1
(43) Pub. Date: Oct. 1, 2026

(54) Optical Waveguide Color Center Creation System

(71) Applicant: The Boeing Company, Arlington, VA (US)

(72) Inventor: Brett Alexander Yurash, Venice, CA (US)

(21) Appl. No.: 19/094,825

(22) Filed: Mar. 29, 2025

(51) Int. Cl. H01S 3/102; G02B 6/122; H01S 3/13; H10D 48/00

(52) U.S. Cl. CPC H01S 3/1022; G02B 6/122; H01S 3/1305; H10D 48/383

(57) ABSTRACT

An optical waveguide system comprising a primary optical waveguide and a color center generation optical waveguide. The primary optical waveguide comprises a material at a location in the primary optical waveguide that can support formation of a color center. The color center generation optical waveguide has an output positioned substantially perpendicular to a direction of light travel at the location in the primary optical waveguide. The output is directed at the location.

### FIELD

The present disclosure relates generally to optical waveguide systems and in particular, to optical waveguide configurations that enable creation of color centers in optical waveguides.

### BACKGROUND

Optical waveguides have color centers. A color center in an optical waveguide is a defect, imperfection, or other anomaly within material forming the optical waveguide. For example, the defect can be a point defect in a crystal lattice that can absorb and emit light at specific wavelengths. These types of defects can arise when one or more atoms in a crystal is missing or replaced by a different atom resulting in localized electronic states that interact with photons.

A color center can operate as a localized light emission structure. This color center can emit light at specific wavelengths. This color center light can be a single photon or broadband of light when excited by light traveling through the optical waveguide. The manner in which light is emitted from a color center can be created to have specific optical and quantum properties.

With these properties, a color center in an optical waveguide can have many applications. For example, an optical waveguide with the color center can be used in quantum systems. For example, this optical waveguide can be a single photon source for optical computing and security communications.

In another example, an optical waveguide with the color center can be used in a sensor. The properties of light generated by the color center can change in response to changes in a temperature, a strain, an electric field, or a magnetic field.

### SUMMARY

An embodiment of the present disclosure provides an optical waveguide system comprising a primary optical waveguide and a color center generation optical waveguide. The primary optical waveguide comprises a material at a location in the primary optical waveguide that can support formation of a color center. The color center generation optical waveguide has an output positioned substantially perpendicular to a direction of light travel at the location in the primary optical waveguide. The output is directed at the location.

Another embodiment of the present disclosure provides an optical waveguide system comprising a primary optical waveguide, color center generation optical waveguide, and a gap between the primary optical waveguide and the output of the color center generation optical waveguide. The primary optical waveguide comprises a material at a location in the primary optical waveguide that can support formation of a color center. The color center generation optical waveguide with a tapered section having an output positioned substantially perpendicular to a direction of light travel at the location in the primary optical waveguide. The output is directed at the location.

Still another embodiment of the present disclosure provides a method for creating a color center. Characteristics are selected for a laser beam that creates the color center. The laser beam is transmitted at a location for the color center in a primary optical waveguide, wherein the laser beam is transmitted from a color output of a color center generation optical waveguide without coupling the laser beam to optical modes for the primary optical waveguide.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of a photonic processing system in which illustrative embodiments may be implemented;

FIG. 2 is an illustration of a block diagram of a color center creation environment in accordance with an illustrative embodiment;

FIG. 3 is an illustration of a top view of optical waveguides in an optical waveguide system in accordance with an illustrative embodiment;

FIG. 4 is an illustration of a cross-sectional view of a primary optical waveguide in accordance with an illustrative embodiment;

FIG. 5 is an illustration of a composite top view of optical waveguides in an optical waveguide system in accordance with an illustrative embodiment;

FIG. 6 is an illustration of a cross-sectional view of a primary optical waveguide in accordance with an illustrative embodiment;

FIG. 7 is an illustration of a top view of optical waveguides in an optical waveguide system in accordance with an illustrative embodiment;

FIG. 8 is an illustration of a top view of optical waveguides in an optical waveguide system in accordance with an illustrative embodiment;

FIG. 9 is an illustration of a top view of optical waveguides in an optical waveguide system in accordance with an illustrative embodiment;

FIG. 10 is an illustration of a flowchart of a process for getting a color center in accordance with an illustrative embodiment;

FIG. 11 is an illustration of a flowchart of a process for determining whether a color center has been created in accordance with an illustrative embodiment;

FIG. 12 is an illustration of a flowchart of a process for transmitting a laser beam in accordance with an illustrative embodiment;

FIG. 13 is an illustration of a flowchart of a process for transmitting a laser beam in accordance with an illustrative embodiment;

FIG. 14 is an illustration of a flowchart of a process for coupling an input in a waveguide in accordance with an illustrative embodiment;

FIG. 15 is an illustration of a flowchart of a process for routing light generated from transmitting a laser beam through a primary waveguide in accordance with an illustrative embodiment; and

FIG. 16 is an illustration of a flowchart of a process for generating a color center in accordance with an illustrative embodiment.

### DETAILED DESCRIPTION

The illustrative embodiments recognize and take into account one or more different considerations as described herein. For example, the illustrative embodiments recognize and take into account that current techniques for creating color centers may not provide a desired level of quality in an optical waveguide or may not provide a desired level of precision in color center placement in the optical waveguide.

One current technique involves pick and place heterogeneous integration in which color center materials are fabricated and then placed on a desired location on the optical waveguide. This technique has very low yields.

Another technique involves creating color centers using ion implantation. Ion implantation can be performed using surface masking with the ion beam or a focused ion beam. This technique can result in residual lattice damage that degrades the performance of the optical waveguide. Further, this technique also introduces an additional process in the fabrication process flow. This additional process involves moving the substrate on which the optical waveguide with the color center is being fabricated from one station to another station. The substrate can be a wafer or other type of substrate. Equipment used for ion implantation can also be complex, large and expensive.

Another technique is focused electron beam irradiation. This type of color center generation has poor depth resolution for color center placement resulting from the long penetration depth of the electrons. Further, bulky, expensive, and specialized equipment is needed for this type of color center generation.

Color centers can also be created for an optical waveguide through direct writing using laser beams. The laser beams used can be near infrared (NIR) laser beams and ultraviolet (UV) laser beams. The use of laser beams, however, has poor depth resolution for color center placement. Also, the use of laser beams can also result in significant surface damage caused by laser ablation. This type of damage can impact the performance of the optical waveguide in a negative manner.

Further, laser-based techniques also can involve using confocal microscopy setups. Additionally, the generation of color centers are monitored at cryogenic temperatures and cryogenic confocal microscopy is a time-consuming and difficult process to perform. The setups require moving the wafer or substrate on which the optical waveguide is being fabricated to another station for confocal microscopy.

These different techniques can add additional steps in the fabrication process flow. Further, these different techniques also involve complex equipment configuration and setup.

Further, with current techniques for creating color centers, more than one color center may be created. These additional color centers may be in locations other than a desired location within the optical waveguide.

Thus, it is desirable to have a method, apparatus, and system that can operate to create color centers with a greater level of precision and less complexity as compared to current techniques. In one illustrative example, photonic structures are present that enable the creation of color centers in a photonic integrated circuit. Photonic structures are materials or devices that manipulate light through at least one of reflection, refraction, diffraction, or interference, enabling functions like waveguiding, filtering, and optical confinement in applications such as communications, sensing, and quantum technologies.

The color centers can also be referred to as solid-state quantum defects or defects in a photonic integrated circuit. A photonic circuit is an integrated system of optical components. These components can be waveguides, modulators, and detectors that process and transmit light signals. These circuits can have applications in communication, sensing, and computing in a manner similar to how electronic circuits process electrical signals.

In one illustrative example, a number of optical waveguides route laser beam pulses to an area of interest in a primary optical waveguide. As used herein, a “number of” when used with reference to items mean one or more items. For example, a number of optical waveguides is one or more optical waveguides.

These laser beam pulses have characteristics that can create one or more color centers in a defined area of interest. This area of interest is also referred to as a location in the optical waveguide.

One illustrative example enables color center creation after the primary photonic circuit has been fabricated. Once the number of color centers are created, the optical waveguides used to deliver laser beam pulses for color center creation remain without needing further processing to be removed. These waveguides do not substantially affect the performance of the photonic circuit.

Further, an illustrative example can include other circuit components that enable real time in-situ monitoring of the color center creation process. This monitoring enables the deterministic placement of a desired number of color centers in the area of interest.

This color center creation in the illustrative example is in contrast to current techniques. Current techniques have drawbacks including at least one of requiring that the creation occurs at an early stage of the photonic circuit fabrication process, not being amenable to in-situ feedback of the creation process, not having a well-defined locality to color center placement, damaging the host material, and using expensive, or bulky equipment that adds to the manufacturing process complexity.

Further, the phrase “at least one of,” when used with a list of items, means different combinations of one or more of the listed items can be used, and only one of each item in the list may be needed. In other words, “at least one of” means any combination of items and a number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combination of these items can be present. In some illustrative examples, “at least one of” can be, for example, without limitation, two of item A; one of item B; and ten of item C; four of item B and seven of item C; or other suitable combinations.

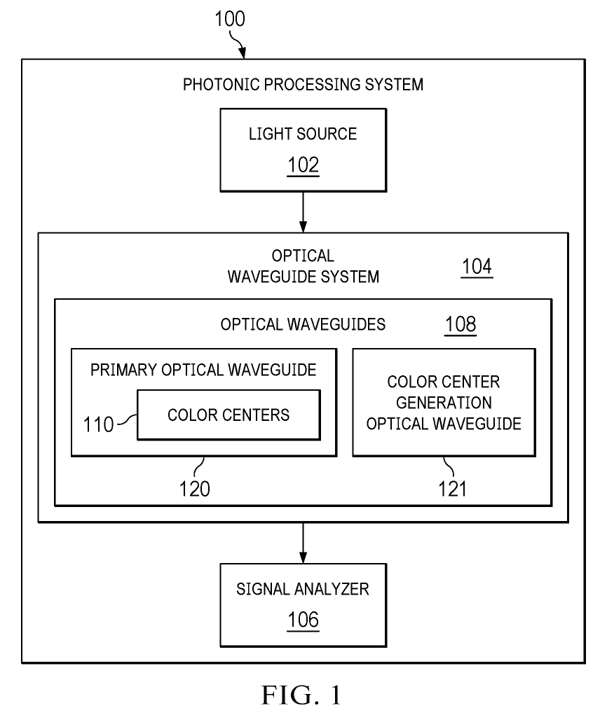

With reference now to the figures and, in particular, with reference to FIG. 1, an illustration of a photonic processing system is depicted in which illustrative embodiments may be implemented. In this illustrative example, photonic processing system 100 comprises light source 102, optical waveguide system 104, and signal analyzer 106. Photonic processing system 100 can be used in quantum processing, sensors, communications, or other suitable applications.

In this illustrative example, light source 102 provides light to optical waveguide system 104. In this illustrative example, light source 102 can take a number of different forms. For example, light source can be selected from at least one of a laser beam generator, a light-emitting diode (LED), a single photon source, or other types of light sources.

In this example, optical waveguide system 104 includes optical waveguides 108. These optical waveguides are comprised of materials that can propagate light. For example, these optical waveguides can be comprised of material selected from at least one of silicon, silicon carbide, silicon nitride, aluminum nitride, silicon dioxide, lithium niobate, aluminum nitride, silica glass, phosphate glass, sapphire, borosilicate glass, and other suitable materials that may be used to fabricate optical waveguides that propagate light.

As depicted, optical waveguides 108 are comprised of primary optical waveguide 120 and color center generation optical waveguide 121.

Primary optical waveguide 120 includes a number of color centers 110. In this illustrative example, color center generation optical waveguide 121 can be operated during manufacturing of optical waveguides 108 to propagate a laser beam to create the number of color centers 110 in primary optical waveguide 120. This optical waveguide is not removed after manufacturing of optical waveguide system 104 is completed.

During operation of photonic processing system 100, this light is transmitted into optical waveguide system 104. The light propagates through optical waveguide system 104. The light propagates through primary optical waveguide 120 and excites a number of color centers 110 within primary optical waveguide 120. This excitement can generate additional light. This additional light is referred to as color center light.

This color center light is detected by signal analyzer 106. Signal analyzer 106 is a component that performs detection and processing of the color center light as well as any other light propagating through optical waveguides 108 that can be detected.

Signal analyzer 106 can include a photodetector system to detect the light output by optical waveguide system 104. Additionally, signal analyzer 106 can also include a processor, storage, memory, and other components used to analyze color center light detected in optical waveguide system 104. Signal analyzer 106 can analyze the color center light for quantum processing, sensors, communications, or other suitable applications. In this example, when photonic processing system 100 takes the form of a temperature sensor, signal analyzer 106 detects light emitted by the number of color centers 110. The temperature is determined based on the characteristics of the light emitted by the number of color centers 110. As another example, photonic processing system 100 operates as a memory, and light emitted by the number of color centers 110 can be analyzed by signal analyzer 106 to determine the data stored using the number of color centers 110.

Other optical waveguides can also be present within optical waveguides 108 in addition to these optical waveguides. Further, the light emitted by the light source can also propagate to other optical waveguides in optical waveguides 108 in addition to or in place of primary optical waveguide 120 during operation of photonic processing system 100. For example, other optical waveguides can be present in optical waveguides 108 that also include one or more color centers that can be excited in response to light from light source 102.

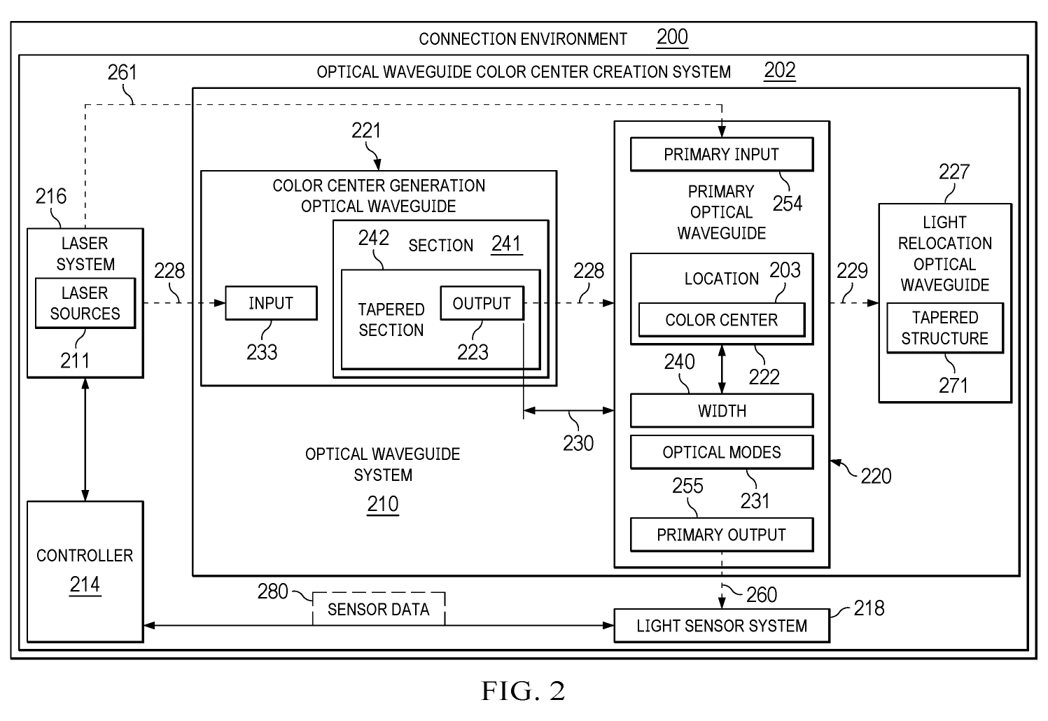

With reference now to FIG. 2, an illustration of a block diagram of a color center creation environment is depicted in accordance with an illustrative embodiment. In this illustrative example, optical waveguide color center creation system 202 in color center creation environment 200 operates to generate color center 203.

In this illustrative example, optical waveguide color center creation system 202 includes a number of different components. As depicted, optical waveguide color center creation system 202 comprises optical waveguide system 210, controller 214, laser system 216, and light sensor system 218. Optical waveguide system 210 is an example of an implementation for optical waveguide system 104 in FIG. 1.

Laser system 216 is configured to generate laser beams used in creating color center 203. As depicted, laser system 216 comprises a number of laser sources 211. Each laser source can generate a laser beam.

As depicted, optical waveguide system 210 comprises primary optical waveguide 220 and color center generation optical waveguide 221. Primary optical waveguide 220 is an example of primary optical waveguide 120 in FIG. 1. In this example, primary optical waveguide 220 is comprised of a material at location 222 in the primary optical waveguide 220 that can support formation of color center 203. Primary optical waveguide 220 can be comprised of a first material at location 222 and color center generation optical waveguide 221 can be comprised of a second material that is different from the first material. In other examples, these waveguides can be comprised of the same material. Materials at location 222 can include at least one of silicon carbide, silicon nitride, silicon, diamond, boron nitride, aluminum nitride, lithium niobate. For example, primary optical waveguide 220 can be silicon nitride and location 222 can be a diamond. In this example, location 222 is a region in which color center generation is desired to generate color center 203. This region can be specified based on the design of primary optical waveguide 220.

Further, the design of location 222 can be such that the generation of color center 203 can be more accurately selected in the direction across the cross-section of primary optical waveguide 220. For example, primary optical waveguide 220 has width 240 at location 222 that is narrower than other portions of primary optical waveguide 220. For example, width 240 is a width of the cross-section of primary optical waveguide 220. This selection of width 240 enables more precisely locating color center 203 in primary optical waveguide 220.

In this example, color center generation optical waveguide 221 is an example of color center generation optical waveguide 121 in FIG. 1. In this illustrative example, color center generation optical waveguide 221 has input 233 and output 223. In one illustrative example, color center generation optical waveguide 221 has section 241 that narrows to form tapered section 242 including output 223. With this example, output 223 forms a tip for tapered section 242.

The manner in which section 241 tapers to form tapered section 242 can be selected to provide desired characteristics for laser beam 228 as laser beam 228 is transmitted from output 223. For example, the size or diameter of laser beam 228, the amount of reflection, and other properties of laser beam 228 can be affected based on the design of tapered section 242.

Input can be coupled to a laser source in laser sources 211 that generates laser beam 228 that is transmitted from output 223 through primary optical waveguide 220. Laser beam 228 can be selected from a group comprising a pulsed laser beam and a continuous laser beam. Laser beam 228 has beam characteristics selected from at least one of a number of pulses, an energy per pulse, a temporal pulse width, or a wavelength that are selected to generate color center 203 at location 222. The wavelength can be above the bandgap or below the bandgap of the material in primary optical waveguide 220 at location 222. Selecting the wavelength to be above or below the bandgap of the material can result in multi-photoionization that results in the generation of defects for a color center. Characteristics selected for laser beam 228 can vary depending on the material used in primary optical waveguide 220 at location 222.

In one illustrative example, these beam characteristics are selected to create a defect to form the color center 203. In another example, these beams are selected to create a defect to form the color center and subsequently to anneal the defect to at least one of form or modify the color center.

For example, laser beam 228 has a first wavelength selected to create the defect and laser beam 228 has a second wavelength selected to anneal the defect.

Color center generation optical waveguide 221 has output 223 that is positioned substantially perpendicular to a direction of light travel at location 222 in primary optical waveguide 220. In this example, output 223 is directed at location 222.

In this example, substantially perpendicular means perpendicular or almost perpendicular. In this example, output 223 of color center generation optical waveguide 121 is positioned substantially perpendicular such that light from a laser beam 228 transmitted from output 223 into primary optical waveguide 220 at location 222 has an angle such that the light from laser beam 228 propagating in primary optical waveguide 220 does not couple to optical modes 231 for primary optical waveguide 220. The selection of the wavelength for the laser beam can also impact the amount of coupling. The lack of propagation through primary optical waveguide 220 resulting from coupling can reduce the probability that color center 203 is generated outside of location 222.

Further, location 222 can be an elongate region across primary optical waveguide 220 in a direction where the laser beam 228 transmitted from output 223 enters primary optical waveguide 220 and exits primary optical waveguide 220.

In this illustrative example, the propagation of laser beam 228 through location 222 for primary optical waveguide 220 results in the generation of color center 203. In this example, the generation of color center 203 or additional color centers outside location 222 is undesirable. The reduction in this type of generation of color centers can occur when coupling of laser beam 228 to optical modes 231 for primary optical waveguide 220 is absent or reduced.

In this example, optical modes 231 are patterns of electromagnetic field distribution that can travel through primary optical waveguide 220. In this example, coupling to these optical modes is undesirable because the coupling can cause laser beam 228 to propagate to other locations within primary optical waveguide 220 outside of location 222. As a result, a number of color centers can be generated outside of location 222.

In some illustrative examples, optical waveguide system 210 can also include light relocation optical waveguide 227. This waveguide is an optional waveguide and may not be present in all examples.

With this example, color center generation optical waveguide 221 is located on a first side of primary optical waveguide 220 and light relocation optical waveguide 227 is located on a second side of primary optical waveguide 220. In other words, light relocation optical waveguide 227 is positioned to capture or collect light 229 exiting primary optical waveguide 220 and propagate light 229 to another location without light 229 substantially interacting with primary optical waveguide 220.

With this example, light relocation optical waveguide 227 is positioned to collect light 229 exiting primary optical waveguide 220 in which light 229 results from laser beam 228 transmitted by color center generation optical waveguide 221 that propagates through location 222 in primary optical waveguide 220 and exits primary optical waveguide 220. In other words, laser beam 228 emitted from output 223 propagates through location 222 without being coupled to propagate in a direction of light travel for primary optical waveguide 220. Thus, light 229 exits on the other side of primary optical waveguide 220 and can be collected by light relocation optical waveguide 227.

In one illustrative example, light relocation optical waveguide 227 has tapered structure 271 that collects light 229 exiting primary optical waveguide 220. With this example, a first end of light relocation optical waveguide 227 closer to primary optical waveguide 220 is broader than a second end of light relocation optical waveguide 227.

In this illustrative example, optical waveguide color center creation system 202 can operate to create color center 203 in location 222 in primary optical waveguide 220 in optical waveguide system 210. In this example, optical waveguide color center creation system 202 also includes controller 214, laser system 216, and light sensor system 218.

In this illustrative example, gap 230 is present between primary optical waveguide 220 and output 223 of color center generation optical waveguide 221. Gap 230 is a distance or separation between output 223 and primary optical waveguide 220.

In selecting gap 230, a number of factors can be taken into account. For example, a larger gap will ensure guided light in primary optical waveguide 220 does not couple into color center generation optical waveguide 221. However, laser beam 228 that exits the color center generation optical waveguide 221 will expand as the light from laser beam 228 approaches location 222 where the color center 203 is desired in primary optical waveguide 220. Thus, gap 230 should not be so large such that the precision with which color center 203 can be located is be reduced.

In this illustrative example, laser beam 228 entering color center generation optical waveguide 221 is transmitted from output 223 into and through primary optical waveguide 220. This laser beam does not substantially couple to optical modes 231 for primary optical waveguide 220.

In this example, generation of color center 203 in location 222 in primary optical waveguide 220 is controlled by controller 214. Controller 214 can be implemented in software, hardware, firmware or a combination thereof. When software is used, the operations performed by controller 214 can be implemented in program instructions configured to run on hardware, such as a processor unit. When firmware is used, the operations performed by controller 214 can be implemented in program instructions and data and stored in persistent memory to run on a processor unit. When hardware is employed, the hardware can include circuits that operate to perform the operations in controller 214.

In the illustrative examples, the hardware can take a form selected from at least one of a circuit system, an integrated circuit, an application-specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field-programmable logic array, a field-programmable gate array, and other suitable hardware devices. Additionally, the processes can be implemented in organic components integrated with inorganic components and can be comprised entirely of organic components excluding a human being. For example, the processes can be implemented as circuits in organic semiconductors.

For example, controller 214 controls the operation of laser system 216 to generate laser beam 228. Further, controller 214 can control the characteristics from laser beam 228 emitted by laser sources 211 in laser system 216. Further, the operation of laser system 216 by controller 214 can be performed based on feedback received from light sensor system 218.

Light sensor system 218 is comprised of a number of sensors. The sensors can include a photodiode, an avalanche photodiode, a phototransistor, a photomultiplier tube, a silicon photomultiplier, a charged coupled device, and other suitable types of sensors.

In this illustrative example, controller 214 creates color center 203 in location 222 using a process that uses laser system 216 and light sensor system 218. For example, controller 214 selects a number of beam characteristics for laser beam 228 that creates color center 203. Controller 214 transmits laser beam 228 at location 222 for color center 203 in primary optical waveguide 220 using laser system 216. In this example, laser beam 228 is transmitted by laser system 216 into input 233 of color center generation optical waveguide 221 and is transmitted from output 223 of color center generation optical waveguide 221 through primary optical waveguide 220 without coupling laser beam 228 to optical modes 231 for primary optical waveguide 220.

Controller 214 also transmits test laser beam 261 into primary input 254 of primary optical waveguide 220 using laser system 216. Test laser beam 261 propagates through location 222 in primary optical waveguide 220. If color center 203 is present in location 222, laser beam 261 propagating through location 222 of primary optical waveguide 220 causes an excitation of color center 203 that results in generation of color center light. This color center light can be a portion of or all of light 260 emitted from primary output 255 in primary optical waveguide 220.

Controller 214 detects light 260 at primary output 255 of primary optical waveguide 220 in response to test laser beam 261. Light 260 is detected using light sensor system 218. For example, light sensor system 218 can be configured to detect color center light in light 260. If color center 203 is not present, the absence of this light is detected by light sensor system 218.

In this example, light sensor system 218 generates sensor data 280 in response to detecting light 260. This sensor data is sent by light sensor system 218 to controller 214 for analysis.

Sensor data 280 provides feedback as to whether color center 203 has been generated. For example, color center light can be created having characteristics such as a particular wavelength. Light 260 having this wavelength indicates that color center 203 has been generated using laser beam 228.

Controller 214 determines whether light 260 detected by sensor system 218 has characteristics indicating that color center 203 is present using sensor data 280. For example, the wavelength for the color center generation light can be different wavelengths from test laser beam 261 and from laser beam 228.

Controller 214 repeats selecting the number of beam characteristics for laser beam 228 and transmitting laser beam 228 at location 222 for color center 203 in primary optical waveguide 220 in response to an absence of the characteristics indicating color center 203 is present.

In this example, this repeating of the process can involve changing the number of laser beam characteristics that are selected. For example, at least one of a number of pulses, an energy per pulse, a temporal pulse width, or a wavelength are selected to generate the color center at the location. In other examples, the characteristics are not changed in making a selection. In this case, the transmission of laser beam 228 performs using the same characteristics.

In this example, controller 214 can create color center 203 using real-time feedback from transmitting laser beam 228. In one illustrative example, laser beam 228 is transmitted. Thereafter, test laser beam 261 is transmitted. In another illustrative example, both laser beam 228 and test laser beam 261 can be transmitted at the same time or overlap in transmission times.

This type of color center generation and detection can be performed using the same equipment. No need is present to move the substrate on which optical waveguide system 210 is located to another location or piece of equipment.

Thus, optical waveguide system 210 enables color center creation within a waveguide using another waveguide that is formed as part of this optical waveguide system. In other words, the waveguides depicted in optical waveguide system 210 can be constructed during the fabrication. As part of the fabrication process, color center generation optical waveguide 221 can operate to propagate laser beam 228 in a manner that causes the creation of color center 203 in location 222 of primary optical waveguide 220. This creation of color center 203 can be performed without needing to move the substrate on which this waveguide system is located to another station or piece of equipment. The substrate can be a silicon wafer, glass, or silicon carbide wafer. As another example, the substrate can be a substrate that uses non-silicon material such as gallium nitride, aluminum nitride, sapphire substrate, an epitaxial growth on substrate, or some other suitable type of substrate.

As a result, additional operations where the substrate is moved to another station or piece of equipment is unnecessary in these illustrative examples. For example, moving the substrate to another station for confocal microscopy is unnecessary in the illustrative examples.

The illustration of color center creation environments in FIG. 2 is not meant to imply physical or architectural limitations to the manner in which an illustrative embodiment may be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

For example, one or more color centers can be created in location 222 in addition to color center 203. In yet other illustrative examples, color centers can be created in other locations in addition to location 222 within primary optical waveguide 220. For example, one or more color center generation optical waveguides can be used in addition to color center generation optical waveguide 221 to create these color centers and other locations. As another example, laser beam 228 and test laser beam 261 can be transmitted to waveguides through at least one of an air interface, optical fibers, or other optical waveguides.

In yet another example, filters can be used to pass color center lights and light 260. For example, optical filters may be present in the primary optical waveguide to the point that only passes color center light. These filters can pass light having a specific range of wavelengths expected for color center light. In another example, optical filters or other filters may be present in the light sensor system to filter to pass color center light or signals generated from color center light.

In another illustrative example, the determination of whether color center 203 has been created can be determined by detecting that the amount of coupling from the laser beam 228 (color center creation pulsed light) into primary optical waveguide 220 is less than the amount of light emitted from color center 203 into primary optical waveguide 220. This determination allows knowing whether light 260 detected from primary optical waveguide 220 originates from color center 203.

Thus, color center creation can be performed in an optical waveguide system in which a color generation optical waveguide is created on the same substrate as the primary optical waveguide. This color generation optical waveguide is present for the purpose of generating a color center within the primary optical waveguide. This color generation optical waveguide does not need to be removed after creating the color center.

Further, in some illustrative examples, the primary optical waveguide can be tested after the laser beam has been transmitted into and propagates through the location where the color center is desired. This testing can be performed by transmitting light through the primary optical waveguide as would be done during normal operation. The light output of the primary optical waveguide is analyzed to determine whether the light has characteristics indicating that the color center is present. If a color center is not present, a laser beam can be transmitted again with the same or different characteristics for creating the color center.

These different operations can be performed at the same station or location without needing to move the optical waveguide system to another location for testing or inspection by other complex equipment.

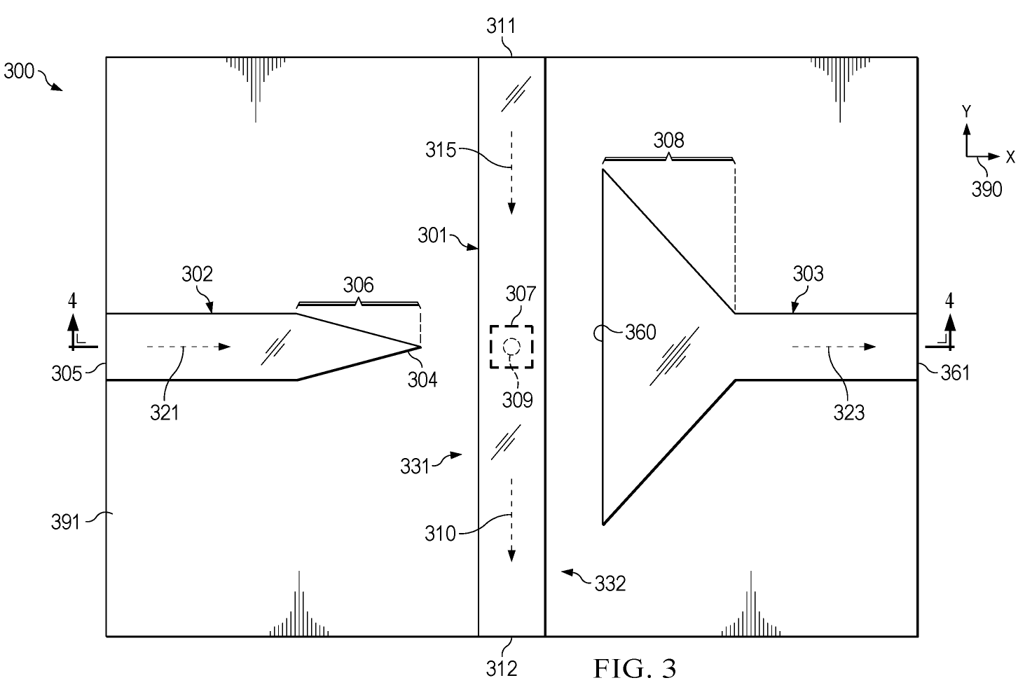

Turning next to FIG. 3, an illustration of a top view of optical waveguides in an optical waveguide system is depicted in accordance with an illustrative embodiment. In this example, optical waveguide system 300 is an example of an implementation of optical waveguide system 210 in FIG. 2.

As depicted, optical waveguide system 300 comprises primary optical waveguide 301, color center generation optical waveguide 302, and light relocation optical waveguide 303. These waveguides are depicted from a top view on an XY plane 390. As shown in this example, these waveguides have been formed on bottom cladding 391. As depicted, color center generation optical waveguide 302 is located on first side 331 of primary optical waveguide and light relocation optical waveguide 303 is located on second side 332 of primary optical waveguide 301 as shown on XY plane 390.

In this illustrative example, color center generation optical waveguide 302 has input 305 and output 304. This output is also referred to as the tip of color center generation optical waveguide 302. As depicted in this example, color center generation optical waveguide 302 has tapered section 306 that tapers down in width at output 304. This taper is selected to focus laser beam 321 to propagate alone a line on which a defect is desired in location 307 to generate color center 309. In other words, the location of the defect for the color center can be more precisely selected along the Y-axis of XY plane 390 using tapered section 306.

In this illustrative example, pulsed laser beam 321 is transmitted into input 305 and propagates through color center generation optical waveguide 302 to be transmitted from output 304 of color center generation optical waveguide 302. This pulsed laser beam can have a wavelength λ1 for defect creation and a wavelength λ2 for annealing. In other words, different pulses can have different wavelengths depending on the type of result desired.

The transmission of laser beam 321 from output 304 results from this laser beam propagating through location 307 in primary optical waveguide 301. As depicted, color center generation optical waveguide 302 is positioned to be perpendicular or substantially perpendicular to the light of travel through primary optical waveguide 301 at location 307. This orientation of laser beam 321 helps to reduce or eliminate coupling of laser beam 321 to modes in primary optical waveguide 301 as laser beam 321 propagates through primary optical waveguide 301. In other words, laser beam 321 enters first side 331 of primary optical waveguide 501 and exits second side 332 of primary optical waveguide 301 on XY plane 390.

In this example, light relocation optical waveguide 503 is designed to collect light 323 resulting from laser beam 321 propagating through primary optical waveguide 301 at location 307 and exiting on second side 332 of primary optical waveguide 301. This light is propagated to another location without light 323 substantially interacting with primary optical waveguide 301. For example, light relocation optical waveguide 303 can perform an off chip dump of light 323. In this illustrative example, light relocation optical waveguide 303 has input 360 and output 361 with tapered structure 308.

Further in this illustrative example, light 315 is an excitation light that can be transmitted into primary input 311 of primary optical waveguide 301. Light 315 has wavelength λ3 that is selected to excite color center 309 in location 307 when this color center is present at this location. This light can be a laser beam, coherent light, polarized light, post light, or other types of light that can cause an excitation of color center 309. In this example, the wavelength is different from wavelength λ1 and wavelength λ2 that can be used for laser beam 321.

When color center 309 is present, color center 309 is excited and emits color center light 310 that is detected at primary output 312. This color center light has wavelength λ4 that is expected in response to excitation of color center 309. During manufacturing of color center 309, this color center light can be used to indicate that color center 309 has been generated. If color center 309 is not present, then light 315 or other light other than color center light 310 is detected at primary output 312. In other words, both light 315 and color center light 310 can be transmitted from primary output 312. The absence of color center light 310 being detected at primary output 312 indicates that color center 309 is not present at location 307.

In the event that color center light 310 is not detected at primary output 312, laser beam 321 can be transmitted with changes in characteristics that are designed to create color center 309. In some cases, laser beam 321 can be retransmitted with the same characteristics. Thus, the detection of light at primary output 312 can be used as feedback to determine whether color center 309 has been generated. Further, this detection can also be used to determine whether color center 309 has the desired characteristics. For example, a specific wavelength may be desired for color center 309. If that wavelength of light is not detected at primary output 312, color center 309 may be present, but is not the correct color center.

After manufacturing of optical waveguide system 300 is complete, primary optical waveguide 301 is used during operation of the system in which this waveguide is located. The other two waveguides, color center generation optical waveguide 302 and light relocation optical waveguide 303 are not used but remain in optical waveguide system 300 during operation of the system. Removal of these waveguides is unnecessary in these examples.

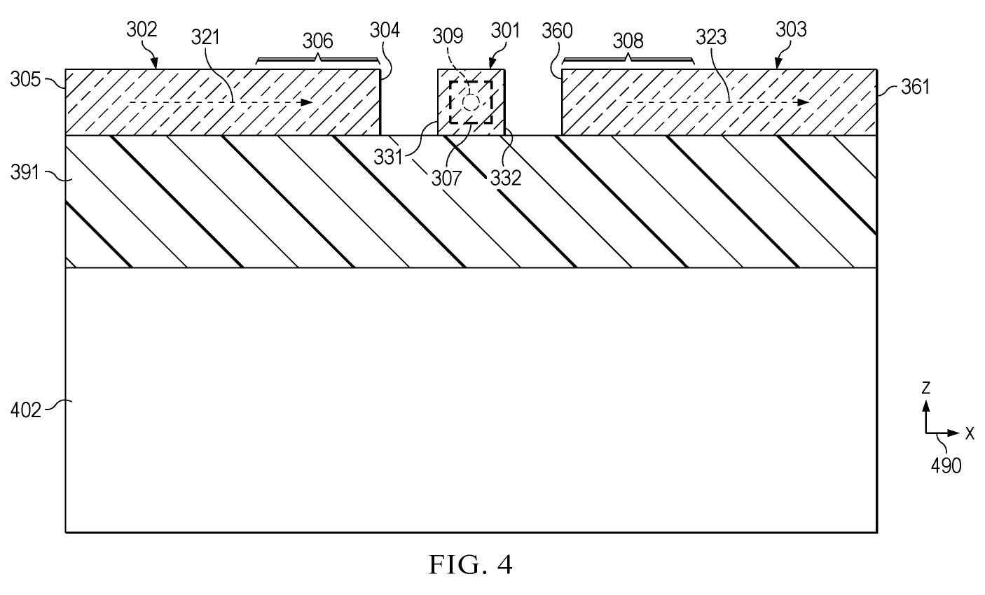

With reference to FIG. 4, an illustration of a cross-sectional view of a primary optical waveguide is depicted in accordance with an illustrative embodiment. In the illustrative examples, the same reference numeral may be used in more than one figure. This reuse of a reference numeral in different figures represents the same element in the different figures.

In this example, a cross-sectional view of optical waveguide system 300 is shown taken along lines 4-4 in FIG. 3. This view of optical waveguide system 300 is on plane XZ 490.

As depicted, primary optical waveguide 301, color center generation optical waveguide 302, and light relocation optical waveguide 303 are formed on bottom cladding 391. This bottom cladding is located on substrate 402. In this example bottom cladding 391 can be selected from a group comprising silicon dioxide, hafnium oxide, sapphire, and some other suitable material.

As depicted in this view, laser beam 321 is emitted from output 304 of color center generation optical waveguide 302. Laser beam 321 enters on first side 331 and with light 323 resulting from laser beam 321, propagates through location 307 and exits through second side 332.

This light is collected at input 360 of light relocation optical waveguide 303 and propagates to be output at another location at output 361.

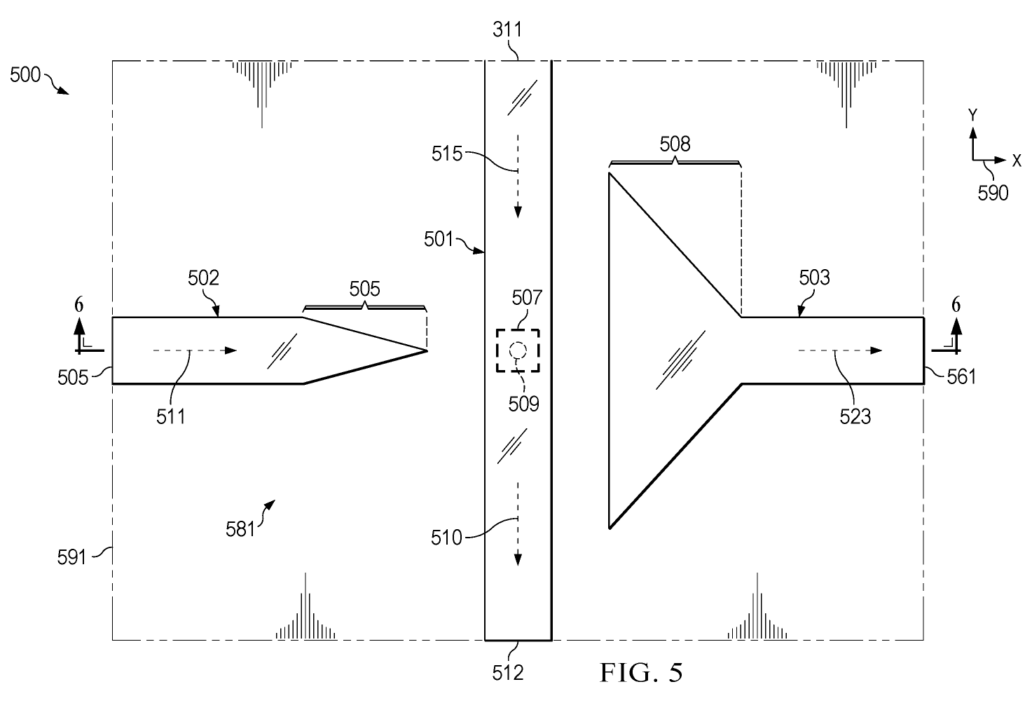

Next in FIG. 5, an illustration of a composite top view of optical waveguides in an optical waveguide system is depicted in accordance with an illustrative embodiment. In this example, optical waveguide system 500 is an example of an implementation of optical waveguide system 210 in FIG. 2.

As depicted, in this composite top view, top cladding 591 is shown with underlying waveguides 581 being visible in top cladding 591. In this example, top cladding 591 can be silicon dioxide, hafnium oxide, or some suitable material. Underlying waveguides 581 in optical waveguide system 500 comprise primary optical waveguide 501, color center generation optical waveguide 502, and light relocation optical waveguide 503. These waveguides are depicted from a top view on an XY plane 590.

As depicted, color center generation optical waveguide 502 has tapered section 505 that tapers down in width. In this illustrative example, pulsed laser beam 511 has a wavelength that is transmitted into and propagates through color center generation optical waveguide 302 to be transmitted into primary optical waveguide 501. This laser beam propagates though location 507 with characteristics selected to generate color center 509.

As depicted, color center generation optical waveguide 502 is positioned to be perpendicular or substantially perpendicular to the light of travel through primary optical waveguide 501 at location 507.

In this example, light relocation optical waveguide 503 is designed to collect light 523 resulting from laser beam 511 propagating through primary optical waveguide 501 at location 507 and exiting primary optical waveguide 501. This light is propagated to another location without light 523 substantially interacting with primary optical waveguide 501. In this example, light relocation optical waveguide 503 has tapered structure 508.

Further in this illustrative example, light 515 is an excitation light that can be transmitted into primary optical waveguide 301. Light 515 has a wavelength that is selected to excite color center 509 in location 307. In this example, the wavelength of light 515 is different from the wavelength used for laser beam 321.

When color center 309 is present, color center 309 is excited and emits color center light 510 that is detected. This color center light has a wavelength that is expected in response to excitation of color center 509. During manufacturing of color center 509, this color center light can be detected to indicate that color center 309 has been generated. If color center 309 is not present, color center light 510 is not detected.

Primary optical waveguide 501 is used during operation of optical waveguide system 300 after manufacturing is complete. The other two waveguides, color center generation optical waveguide 502 and light relocation optical waveguide 503, remain but are not used in these examples.

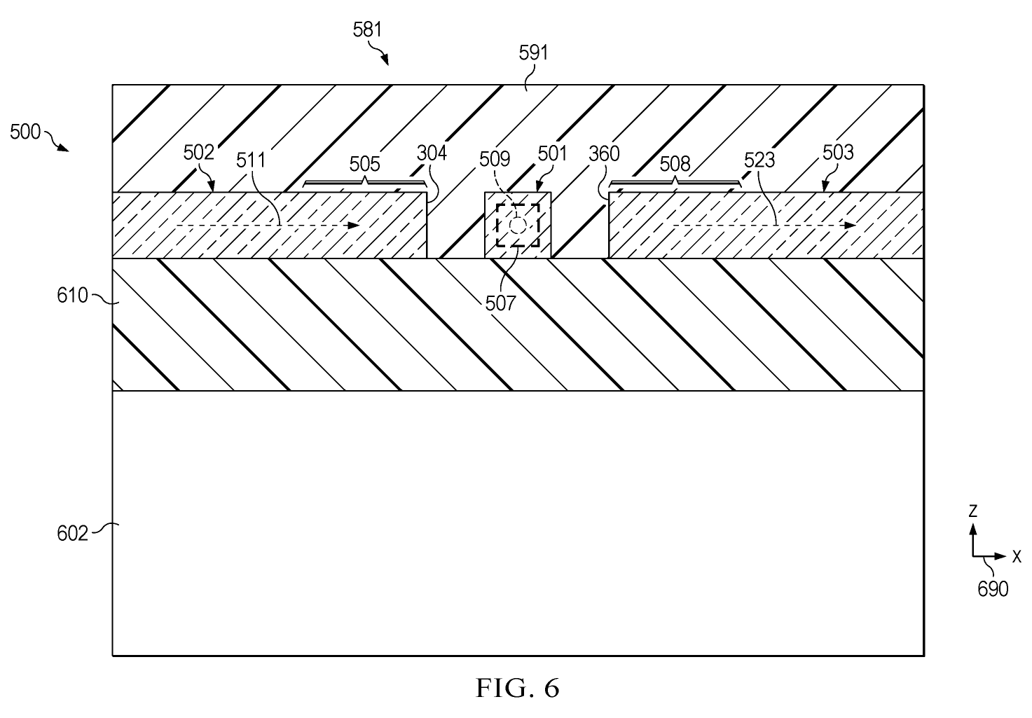

With reference to FIG. 6, an illustration of a cross-sectional view of a primary optical waveguide is depicted in accordance with an illustrative embodiment. This cross-sectional view of optical waveguide system 500 is shown taken along lines 6-6 in FIG. 5. This view of optical waveguide system 500 is on plane XZ 690.

As depicted, primary optical waveguide 501, color center generation optical waveguide 502, and light relocation optical waveguide 503 are formed on bottom cladding 610. This bottom cladding is located on substrate 602. These waveguides are encompassed in top cladding 591.

As depicted in this view, laser beam 511 is emitted from color center generation optical waveguide 302 and propagates through location 507 and with light 523 resulting from laser beam 321 propagating through location 307 and exiting primary optical waveguide 501 to be collected by light relocation optical waveguide 303. This collected light is propagated to another location.

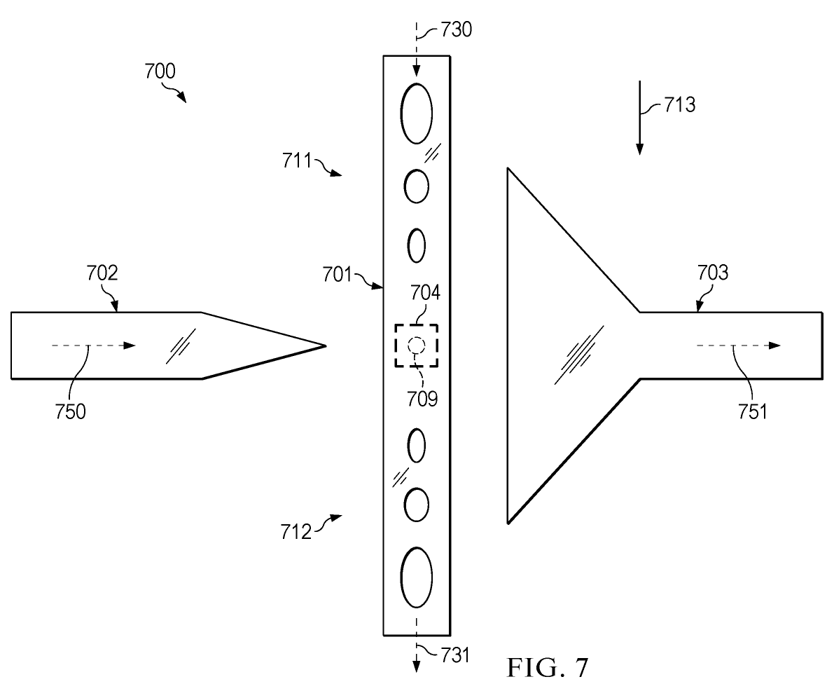

Next in FIG. 7, an illustration of a top view of optical waveguides in an optical waveguide system is depicted in accordance with an illustrative embodiment. Optical waveguide system 700 is an example of an implementation of optical waveguide system 210 in FIG. 2.

As depicted, optical waveguide system 700 comprises primary optical waveguide 701, color center generation optical waveguide 702, and light relocation optical waveguide 703. In this example, primary optical waveguide 701 comprises first openings 711 and second openings 712. First openings 711 are located prior to location 704 in direction 713 of light travel in primary optical waveguide 701. Second openings 712 are located after location 704 in direction 713 of light travel in primary optical waveguide 701. These openings can be used to filter undesired wavelengths of light or pass light with desired wavelengths.

In this example, laser beam 750 is transmitted from color center generation optical waveguide 702 into primary optical waveguide 701. This laser beam propagates through location 704. In this depicted example, light 751 resulting from the propagation of laser beam 750 through location 704 exits primary optical waveguide 701 to be collected by relocation optical waveguide 703. Laser beam 750 has characteristics selected to generate color center 709 in location 704.

During testing to determine whether color center 709 has been created and during normal operation, light 730 enters primary optical waveguide 701. First openings 711 can operate to filter light 730 such that light 730 has a desired wavelength or wavelengths. The number of wavelengths in light 730 filtered by these openings can be used to excite color center 709. The excitation of color center 709 generates color center light 731 that can then be used for further operations.

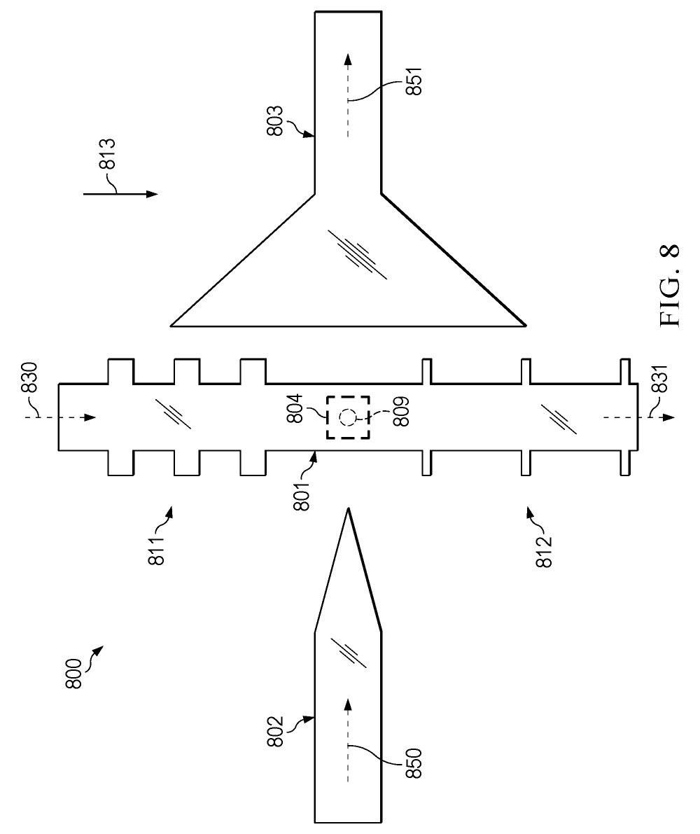

Turning to FIG. 8, an illustration of a top view of optical waveguides in an optical waveguide system is depicted in accordance with an illustrative embodiment. Optical waveguide system 800 is an example of an implementation of optical waveguide system 210 in FIG. 2.

As depicted, optical waveguide system 800 comprises primary optical waveguide 801, color center generation optical waveguide 802, and light relocation optical waveguide 803. In this example, primary optical waveguide 801 comprises first periodic width changes 811 and second periodic width changes 812. First periodic width changes 811 are located prior to location 804 in direction 813 of light travel in primary optical waveguide 801. Second periodic width changes 812 are located after location 804 in direction 813 of light travel in primary optical waveguide 801. These widths can be used to filter undesired wavelengths of light or pass light with desired wavelengths. These types of periodic changes are for bride filters. With this example, primary optical waveguide 801 is also referred to as a bride optical waveguide.

In this example, laser beam 850 is transmitted from color center generation optical waveguide 802 into primary optical waveguide 801. This laser beam propagates through location 804. In this example, light 851 resulting from the propagation of laser beam 750 through location 804 exits primary optical waveguide 801 to be collected by relocation optical waveguide 803. Laser beam 850 has characteristics selected to generate color center 809 in location 804.

During testing to determine whether color center 809 has been created and during normal operation, light 830 enters primary optical waveguide 801. First periodic width changes 811 can operate to filter light 830 such that light 830 has a desired number of wavelengths. The number of wavelengths in light 830 filtered by these openings can be used to excite color center 809. The excitation of color center 809 generates color center light 831.

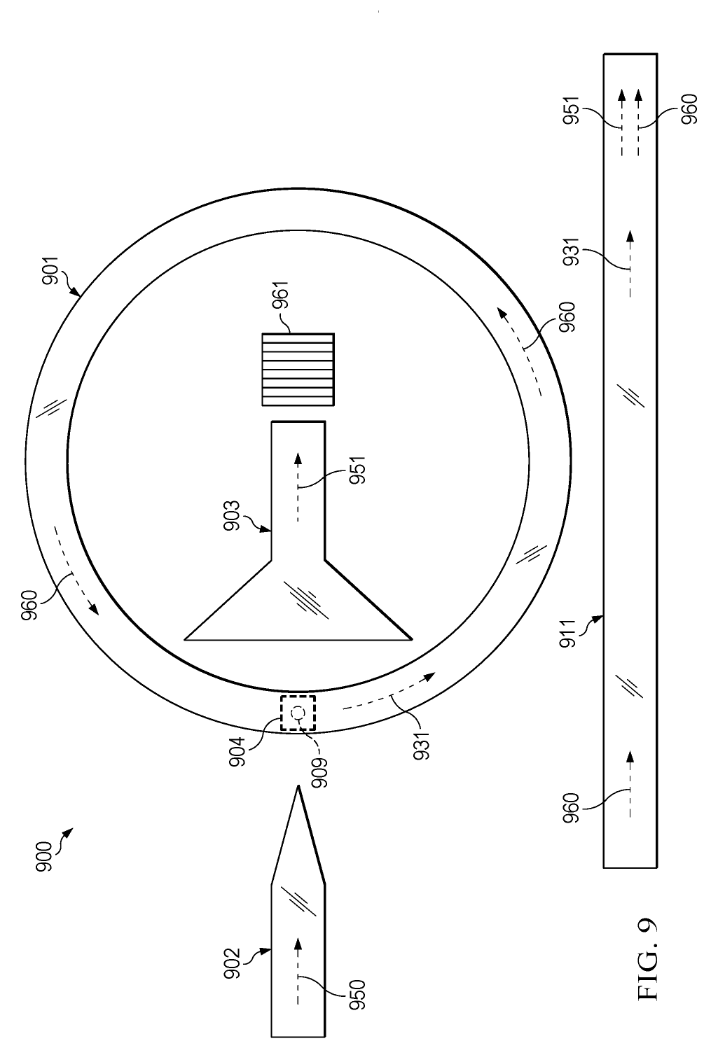

Referring to FIG. 9, an illustration of a top view of optical waveguides in an optical waveguide system is depicted in accordance with an illustrative embodiment. Optical waveguide system 900 is an example of an implementation of optical waveguide system 210 in FIG. 2.

In this example, optical waveguide system 900 comprises microring resonator 901, bus waveguide 911, color center generation optical waveguide 902, and light relocation optical waveguide 903. Microring resonator 901 is an example of an implementation for a primary optical waveguide.

In this example, laser beam 950 is transmitted from color center generation optical waveguide 802 into microring resonator 901. This laser beam propagates through location 904. Laser beam 950 has characteristics selected to generate color center 909 in location 904.

In this illustrative example, light 951 resulting from the propagation of laser beam 950 through location 904 is collected by relocation optical waveguide 903. In this example, relocation optical waveguide 903 is connected to grating coupler 961. These two components propagate light 951 to another location such as off chip.

During testing to determine whether color center 909 has been created and during normal operation, light 960 propagates through bus waveguide 911 and becomes coupled to travel through microring resonator 901. This light travels through location 904 in which color center 909 is located. The excitation of color center 909 generates color center light 931. This light travels through microring resonator 901 and is coupled back into bus waveguide 911. If this color center 909 is not present, color center light 931 is not generated. Instead, other light becomes coupled back into bus waveguide 911.

Thus, this configuration enables creating color center 909 within location 904 without needing to send a laser beam through bus waveguide 911 as part of the color center creation process. In this manner, color centers can be generated more precisely in desired locations. Further, the creation of color centers in other undesired locations can be reduced or eliminated.

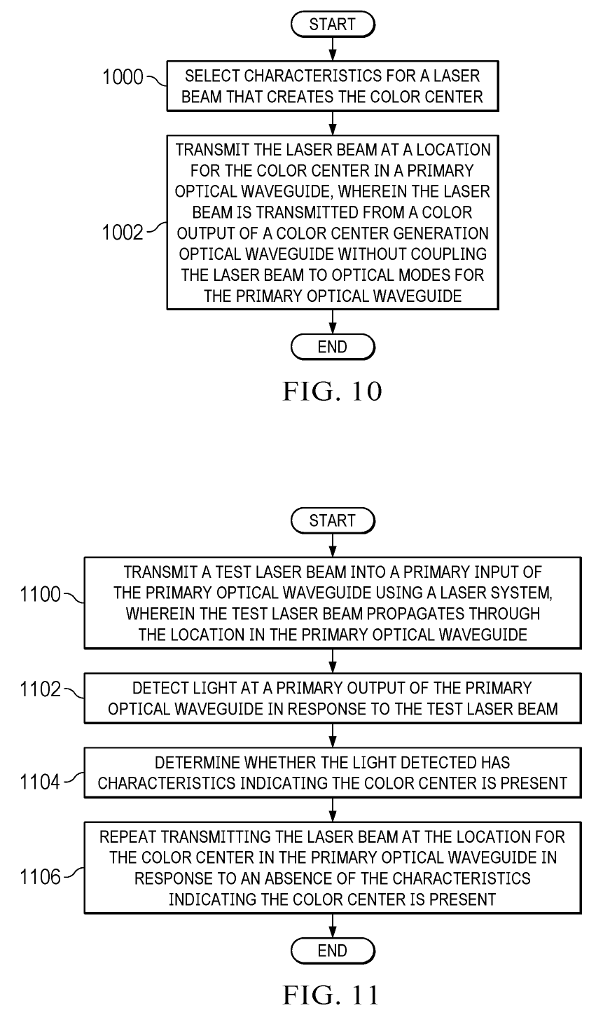

Turning next to FIG. 10, an illustration of a flowchart of a process for getting a color center is depicted in accordance with an illustrative embodiment. The process in FIG. 10 can be implemented in hardware, software, or both. When implemented in software, the process can take the form of program instructions that are run by one of more processor units located in one or more hardware devices in one or more computer systems. For example, the process can be implemented in controller 214 in optical waveguide color center creation system 202 in FIG. 2. This controller can control the operation of different components in optical waveguide system 300 to create color center 203 at location 222 in primary optical waveguide 220.

The process selects characteristics for a laser beam that creates the color center (operation 1000). The process transmits the laser beam at a location for the color center in a primary optical waveguide, wherein the laser beam is transmitted from a color output of a color center generation optical waveguide without coupling the laser beam to optical modes for the primary optical waveguide (operation 1002). The process terminates thereafter.

In operation 1002, the laser beam propagates in a travel direction that is substantially perpendicular to a direction of light travel in the primary optical waveguide at the location such that coupling the laser beam to the optical modes of the primary optical waveguide is avoided. The laser beam is selected from a group comprising a pulsed laser beam and a continuous laser beam. Further, the laser beam has beam characteristics selected from at least one of a number of pulses, an energy per pulse, a temporal pulse width, or a wavelength that are selected to generate the color center at the location, or other characteristics selected to generate color centers.

With reference next to FIG. 11, an illustration of a flowchart of a process for determining whether a color center has been created is depicted in accordance with an illustrative embodiment. The operations in this figure are an example of additional operations that can be performed with the operations in FIG. 10.

The process transmits a test laser beam into a primary input of the primary optical waveguide using a laser system, wherein the test laser beam propagates through the location in the primary optical waveguide (operation 1100). The process detects light at a primary output of the primary optical waveguide in response to the test laser beam (operation 1102).

The process determines whether the light detected has characteristics indicating the color center is present (operation 1104). The process repeats transmitting the laser beam at the location for the color center in the primary optical waveguide in response to an absence of the characteristics indicating the color center is present (operation 1106). The process terminates thereafter. This transmitting of the laser been in operation 1106 can be used for the same or different laser beam characteristics.

In this example, the feedback from detecting the light emitted by the primary optical waveguides from receiving the test laser beam is used to determine whether to repeat transmitting the laser beam through the location.

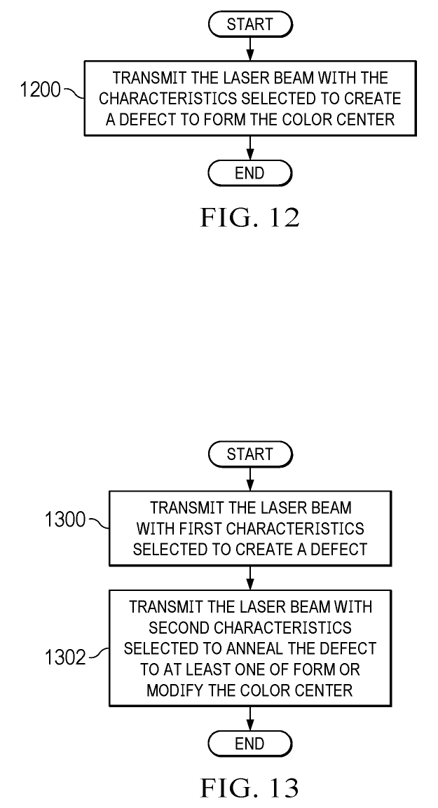

Next in FIG. 12, an illustration of a flowchart of a process for transmitting a laser beam is depicted in accordance with an illustrative embodiment. The operations in this figure are an example of an implementation for operation 1002 in FIG. 10.

The process transmits the laser beam with the characteristics selected to create a defect to form the color center (operation 1200). The process terminates thereafter.

Turning to FIG. 13, an illustration of a flowchart of a process for transmitting a laser beam is depicted in accordance with an illustrative embodiment. The operations in this figure are an example of an implementation for operation 1002 in FIG. 10.

The process transmits the laser beam with first characteristics selected to create a defect (operation 1300). The process transmits the laser beam with second characteristics selected to anneal the defect to at least one of form or modify the color center (operation 1302). The process terminates thereafter.

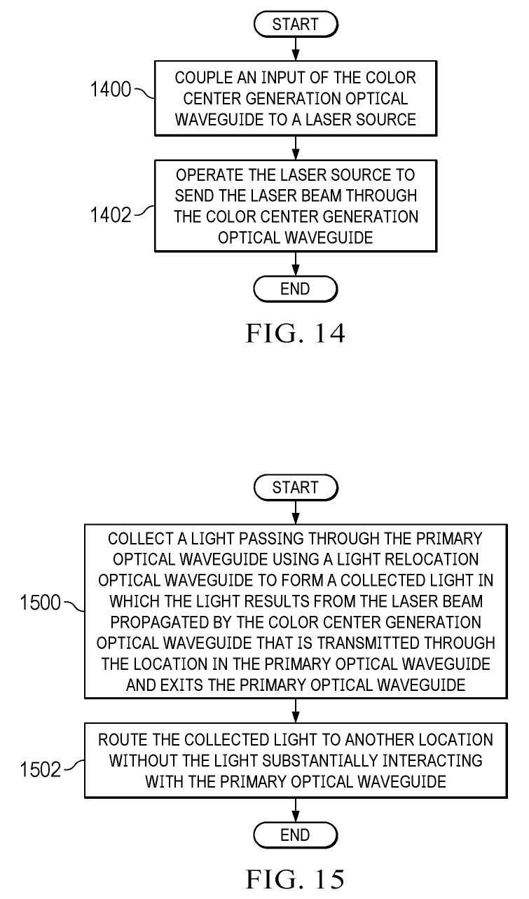

With reference to FIG. 14, an illustration of a flowchart of a process for coupling an input in a waveguide is depicted in accordance with an illustrative embodiment. The operations in this figure are an example of additional operations that can be performed with the operations in FIG. 10.

The process couples an input of the color center generation optical waveguide to a laser source (operation 1400). The process operates the laser source to send the laser beam through the color center generation optical waveguide (operation 1402). The process terminates thereafter.

Turning now to FIG. 15, an illustration of a flowchart of a process for routing light generated from transmitting a laser beam through a primary waveguide is depicted in accordance with an illustrative embodiment. The process in this flowchart is an example of additional operations that can be performed with the operations in FIG. 10.

The process collects a light passing through the primary optical waveguide using a light relocation optical waveguide to form a collected light in which the light results from the laser beam propagated by the color center generation optical waveguide that is transmitted through the location in the primary optical waveguide and exits the primary optical waveguide (operation 1500). The process routes the collected light to another location without the light substantially interacting with the primary optical waveguide (operation 1502). The process terminates thereafter.

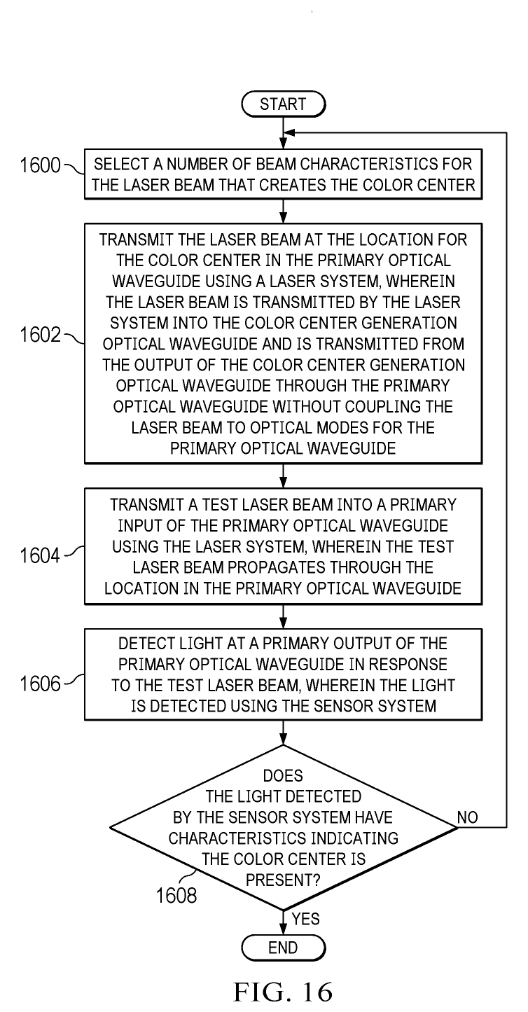

Turning next to FIG. 16, an illustration of a flowchart of a process for generating a color center is depicted in accordance with an illustrative embodiment. The process in FIG. 10 can be implemented in hardware, software, or both. When implemented in software, the process can take the form of program instructions that are run by one of more processor units located in one or more hardware devices in one or more computer systems. For example, the process can be implemented in controller 214 in optical waveguide color center creation system 202 in FIG. 2. This controller can control the operation of different components in optical waveguide system 300 to create color center 203 at location 222 in primary optical waveguide 220.

The process begins by selecting a number of beam characteristics for the laser beam that creates the color center (operation 1600). The process transmits the laser beam at the location for the color center in the primary optical waveguide using a laser system, wherein the laser beam is transmitted by the laser system into the color center generation optical waveguide and is transmitted from the output of the color center generation optical waveguide through the primary optical waveguide without coupling the laser beam to optical modes for the primary optical waveguide (operation 1602).

The process transmits a test laser beam into a primary input of the primary optical waveguide using the laser system, wherein the test laser beam propagates through the location in the primary optical waveguide (operation 1604).

The process detects light at a primary output of the primary optical waveguide in response to the test laser beam, wherein the light is detected using the sensor system (operation 1606). In operation 1606, the sensor system used is designed or configured to detect light having characteristics of the color center that is to be generated at the location. The process determines whether the light detected by the sensor system has characteristics indicating the color center is present (operation 1608).

The process returns to operation 1600 in response to the determination that the light does not have characteristics indicating the color center is present. Otherwise, the process terminates.

When the process returns to operation 1600, the beam characteristics selected can be changed to increase the likelihood of generating a color center at the location.

The flowcharts and block diagrams in the different depicted embodiments illustrate the architecture, functionality, and operation of some possible implementations of apparatuses and methods in an illustrative embodiment. In this regard, each block in the flowcharts or block diagrams can represent at least one of a module, a segment, a function, or a portion of an operation or step. For example, one or more of the blocks can be implemented as program instructions, hardware, or a combination of the program instructions and hardware. When implemented in hardware, the hardware can, for example, take the form of integrated circuits that are manufactured or configured to perform one or more operations in the flowcharts or block diagrams. When implemented as a combination of program instructions and hardware, the implementation may take the form of firmware. Each block in the flowcharts or the block diagrams can be implemented using special purpose hardware systems that perform the different operations or combinations of special purpose hardware and program instructions run by the special purpose hardware.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

Thus, the illustrative examples provide a method, apparatus, and system for color generating color centers in optical waveguides. In one illustrative example, an optical waveguide system comprising a primary optical waveguide and a color center generation optical waveguide. The primary optical waveguide comprises a material at a location in the primary optical waveguide that can support formation of a color center. The color center generation optical waveguide has an output positioned substantially perpendicular to a direction of light travel at the location in the primary optical waveguide. The output is directed at the location.

In the illustrative examples, the color generation optical waveguide is created on the same substrate as the primary optical waveguide. This color generation optical waveguide is present for the purpose of generating a color center within the primary optical waveguide. This color generation optical waveguide does not need to be removed after creating the color center.

Further, in some illustrative examples, the primary optical waveguide can be tested after the laser beam has been transmitted into and propagates through the location where the color center is desired. This testing can be performed by transmitting light through the primary optical waveguide as would be done during normal operation. The light output of the primary optical waveguide is analyzed to determine whether the light has characteristics indicating that the color center is present. If a color center is not present, a laser beam can be transmitted again with the same or different characteristics for creating the color center.

These different operations can be performed at the same station or location without needing to move the optical waveguide system to another location for testing or inspection by other complex equipment.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. An optical waveguide system comprising:
a primary optical waveguide comprising a material at a location in the primary optical waveguide that can support formation of a color center; and
a color center generation optical waveguide with an output positioned substantially perpendicular to a direction of light travel at the location in the primary optical waveguide, wherein the output is directed at the location.

2. The optical waveguide system of claim 1, wherein the color center generation optical waveguide is located on a first side of the primary optical waveguide and further comprising:
a light relocation optical waveguide located on a second side of the primary optical waveguide, wherein the light relocation optical waveguide is positioned to collect a light exiting the primary optical waveguide and propagate the light to another location without the light substantially interacting with the primary optical waveguide, wherein the light results from a laser beam transmitted by the color center generation optical waveguide that propagates through the location in the primary optical waveguide and exits the primary optical waveguide.

3. The optical waveguide system of claim 2, wherein the light relocation optical waveguide has a tapered structure that collects the light exiting the primary optical waveguide, wherein a first end of the light relocation optical waveguide closer to the primary optical waveguide is broader than a second end of the light relocation optical waveguide.

4. The optical waveguide system of claim 1, wherein a gap is present between the primary optical waveguide and the output of the color center generation optical waveguide.

5. The optical waveguide system of claim 1, wherein a laser beam entering the color center generation optical waveguide and transmitted from the output through the primary optical waveguide does not substantially couple to optical modes for the primary optical waveguide.

6. The optical waveguide system of claim 1, wherein the color center generation optical waveguide has an input configured to be coupled to a laser source that generates a laser beam that is transmitted from the output through the primary optical waveguide.

7. The optical waveguide system of claim 6, wherein the laser beam is selected from a group comprising a pulsed laser beam and a continuous laser beam.

8. The optical waveguide system of claim 6, wherein the laser beam has beam characteristics selected from at least one of a number of pulses, an energy per pulse, a temporal pulse width, or a wavelength that are selected to generate the color center at the location.

9. The optical waveguide system of claim 8, wherein the beam characteristics of the laser beam are selected to create a defect to form the color center.

10. The optical waveguide system of claim 8, wherein the beam characteristics of the laser beam are selected to create a defect and subsequently to anneal the defect to at least one of form or modify the color center.

11. The optical waveguide system of claim 10, wherein the laser beam has a first wavelength selected to create the defect and the laser beam has a second wavelength selected to anneal the defect.

12. The optical waveguide system of claim 1, wherein the primary optical waveguide is comprised of a first material at the location and the color center generation optical waveguide is comprised of a second material that is different from the first material.

13. The optical waveguide system of claim 1, wherein the primary optical waveguide has a width at the location that is narrower than other portions of the primary optical waveguide.

14. The optical waveguide system of claim 1, wherein the color center generation optical waveguide has a section that narrows to form a tapered section including the output.

15. The optical waveguide system of claim 1, wherein the primary optical waveguide comprises:
an optical waveguide;
the location in the optical waveguide with the color center;
a first number of openings in the optical waveguide prior to the location; and
a second number of openings in the optical waveguide after the location.

16. The optical waveguide system of claim 1, wherein primary optical waveguide is a bragg optical waveguide comprising:
an optical waveguide;
the location in the optical waveguide with the color center;
a first number of periodic width changes in the optical waveguide prior to the location; and
a second number of period width changes in the optical waveguide subsequent the location.

17. The optical waveguide system of claim 1, wherein the primary optical waveguide comprises:
a microring resonator with a location for the color center; and
a bus waveguide positioned adjacent to the microring resonator such that the bus waveguide couples light traveling through the microring resonator.

18. The optical waveguide system of claim 17 further comprising:
a light relocation optical waveguide located within the microring resonator, wherein the light relocation optical waveguide collects light exiting the primary optical waveguide and routes the light to another location without the light substantially interacting with the microring resonator and the bus waveguide, wherein a first end of the light relocation optical waveguide closer to the primary optical waveguide is broader than a second end of the light relocation optical waveguide that propagates the light to the another location without the light substantially interacting with the microring resonator and the bus waveguide.

19. The optical waveguide system of claim 1 further comprising:
a laser system;
a light sensor system; and
a controller configured to perform operations comprising:
selecting a number of beam characteristics for a laser beam that creates the color center;
transmitting the laser beam at the location for the color center in the primary optical waveguide using a laser system, wherein the laser beam is transmitted by the laser system into the color center generation optical waveguide and is transmitted from the output of the color center generation optical waveguide through the primary optical waveguide without coupling the laser beam to optical modes for the primary optical waveguide;
transmitting a test laser beam into a primary input of the primary optical waveguide using the laser system, wherein the test laser beam propagates through the location in the primary optical waveguide;
detecting light at a primary output of the primary optical waveguide in response to the test laser beam, wherein the light is detected using the sensor system;
determining whether the light detected by the sensor system has characteristics indicating the color center is present; and
repeating transmitting the laser beam at the location for the color center in the primary optical waveguide in response to an absence of the characteristics indicating the color center is present.

20. An optical waveguide system comprising:
a primary optical waveguide comprising a material at a location in the primary optical waveguide that can support formation of a color center;
a color center generation optical waveguide with a tapered section having an output positioned substantially perpendicular to a direction of light travel at the location in the primary optical waveguide, wherein the output is directed at the location and;
a gap between the primary optical waveguide and the output of the color center generation optical waveguide.

21. A method for creating a color center, the method comprising:
selecting characteristics for a laser beam that creates the color center; and
transmitting the laser beam at a location for the color center in a primary optical waveguide, wherein the laser beam is transmitted from a color output of a color center generation optical waveguide without coupling the laser beam to optical modes for the primary optical waveguide.

22. The method of claim 21 further comprising:
transmitting a test laser beam into a primary input of the primary optical waveguide using a laser system, wherein the test laser beam propagates through the location in the primary optical waveguide;
detecting light at a primary output of the primary optical waveguide in response to the test laser beam;
determining whether the light detected has characteristics indicating the color center is present; and
repeating transmitting the laser beam at the location for the color center in the primary optical waveguide in response to an absence of the characteristics indicating the color center is present.

23. The method of claim 21, wherein transmitting the laser beam comprises:
transmitting the laser beam with the characteristics selected to create a defect to form the color center.

24. The method of claim 21, wherein transmitting the laser beam comprises:
transmitting the laser beam with first characteristics selected to create a defect; and
transmitting the laser beam with second characteristics selected to anneal the defect to at least one of form or modify the color center.

25. The method of claim 21 further comprising:
coupling an input of the color center generation optical waveguide to a laser source; and
operating the laser source to send the laser beam through the color center generation optical waveguide.

26. The method of claim 21 further comprising:
collecting a light passing through the primary optical waveguide using a light relocation optical waveguide to form a collected light in which the light results from the laser beam propagated by the color center generation optical waveguide that is transmitted through the location in the primary optical waveguide and exits the primary optical waveguide; and
routing the collected light to another location without the light substantially interacting with the optical waveguide to the another location without the light substantially interacting with the primary optical waveguide.

27. The method of claim 21, wherein the laser beam propagates in a travel direction that is substantially perpendicular to a direction of light travel in the primary optical waveguide at the location such that coupling the laser beam to the optical modes of the primary optical waveguide is avoided.

28. The method of claim 21, wherein the laser beam is selected from a group comprising a pulsed laser beam and a continuous laser beam.

29. The method of claim 21, wherein the laser beam has beam characteristics selected from at least one of a number of pulses, an energy per pulse, a temporal pulse width, or a wavelength that are selected to generate the color center at the location.
